(19) United States
(12) Patent Application Publication
(10) Pub. No.: US 2019/0058397 A1
(43) Pub. Date: Feb. 21, 2019

(54) HARMONIC MODULATION FOR CHARGE BALANCE OF MULTI-LEVEL POWER CONVERTERS

(71) Applicant: Texas Instruments Incorporated, Dallas, TX (US)

(72) Inventors: Orlando Lazaro, Dallas, TX (US); Kevin Scoones, San Jose, CA (US); Alvaro Aguilar, Irving, TX (US); Jeffrey Anthony Morroni, Parker, TX (US); Reza Sharifi, Sunnyvale, CA (US)

(21) Appl. No.: 15/858,626

(22) Filed: Dec. 29, 2017

Related U.S. Application Data
(60) Provisional application No. 62/545,647, filed on Aug. 15, 2017.

(51) Int. Cl. H02M 3/145; H02M 1/14; H03K 7/08

(52) U.S. Cl. CPC H02M 3/145; H02M 2001/0003; H03K 7/08; H02M 1/14

(57) ABSTRACT

In described examples of methods and control circuitry to control a multi-level power conversion system, the control circuitry generates PWM signals having a duty cycle to control an output signal. The duty cycle is adjustable in different switching cycles. Each switching cycle includes a respective first sub-cycle with a first sub-cycle duration and a respective second sub-cycle with a second sub-cycle duration. The control circuitry controls a given switching cycle's first and second sub-cycle durations to control a voltage across a capacitor of the power conversion system while maintaining the given switching cycle's duty cycle.

### CROSS-REFERENCE TO RELATED APPLICATIONS

This application claims priority to, and the benefit of, U.S. Provisional Patent Application No. 62/545,647, entitled “Harmonic Modulation for Charge Balance of Multi-Level Power Converters,” filed Aug. 15, 2017, the entirety of which is hereby incorporated by reference. This application is related to co-pending and co-assigned patent application Ser. No. ______ (Attorney Docket No. TI-78813), entitled “HYSTERETIC PULSE MODULATION FOR CHARGE BALANCE OF MULTI-LEVEL POWER CONVERTERS”, filed on even date herewith, the entirety of which is hereby incorporated by reference. This application is related to co-pending and co-assigned patent application Ser. No. ______ (Attorney Docket No. TI-78815), entitled “REGULATED SUPPLY FOR POWER CONVERSION SYSTEM CONTROL CIRCUITRY”, filed on even date herewith, the entirety of which is hereby incorporated by reference.

### BACKGROUND

High efficiency power supplies are desirable for battery-operated systems, including mobile phones, tablets, laptops and other user devices. Buck, boost and other two-level DC to DC converters use high and low side drivers to alternately connect a switching node to the input voltage or ground. As a result, the high and low side drivers are sized to withstand the input voltage level, and suffer from high switching losses. Three-level and higher order switching converter circuits use more switching transistors and one or more flying capacitors, resulting in higher effective switching frequency and reduced switching loss. These higher level converters can provide higher power density, with reduced voltage withstanding requirements of the converter switches. However, efficient operation of three-level and higher order switching converters requires charge balance and voltage stability for the flying capacitor. Mismatch in the switching on time causes the flying capacitor voltage to drift. Even with equal charging and discharge times, offsets in the flying capacitor voltage remain. The flying capacitor voltage can be maintained and voltage misbalances can be adjusted by altering the converter duty cycle. For example, one phase can be modulated to regulate the flying capacitor voltage, and the other can be used for output regulation. However, this slows the output regulation loop and transient response is poor. Moreover, this disturbs the output control loop and can lead to asymmetric inductor currents or instability. Valley-mode control can be used to regulate the flying capacitor voltage, but valley-mode control does not work for voltage conversion ratios approaching unity. These flying capacitor voltage mismatch shortcomings prevent or inhibit the ability to realize the benefits of three-level and higher order converters for high efficiency switching power supply applications.

### SUMMARY

In described examples of methods and control circuitry to control a multi-level power conversion system, the control circuitry generates pulse width modulation (PWM) signals having a duty cycle to control an output signal. The duty cycle is adjustable in different switching cycles. Each switching cycle includes a respective first sub-cycle with a first sub-cycle duration and a respective second sub-cycle with a second sub-cycle duration. The control circuitry controls a given switching cycle's first and second sub-cycle durations to control a voltage across a capacitor of the power conversion system while maintaining the given switching cycle's duty cycle.

### BRIEF DESCRIPTION OF THE DRAWINGS

FIG. 1 is a system diagram of a multi-level power conversion system.

FIG. 2 shows graphs of switching node voltage for different levels of output voltage.

FIG. 3 is a graph of normalized inductor current change as a function of output voltage to input voltage ratio for a two-level buck converter and a three-level converter.

FIG. 4 is a graph of flying capacitor voltage as a function of time over several switching cycles.

FIG. 5 is a graph of switch node voltage and inductor current in an example switching cycle in the power conversion system of FIG. 1.

FIG. 6 is a graph of inductor current in an example switching cycle for two different flying capacitor voltage values.

FIG. 7 is a graph of flying capacitor voltage and example ramp signals in the power conversion system of FIG. 1 where the output voltage is less than half the input voltage.

FIG. 8 is a graph of flying capacitor voltage and example ramp signals in the power conversion system of FIG. 1 where the output voltage is greater than half the input voltage.

FIG. 9 is a flow diagram of a method of controlling a multi-level power conversion system.

### DETAILED DESCRIPTION

In the drawings, like reference numerals refer to like elements throughout, and the various features are not necessarily drawn to scale. In this description, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections.

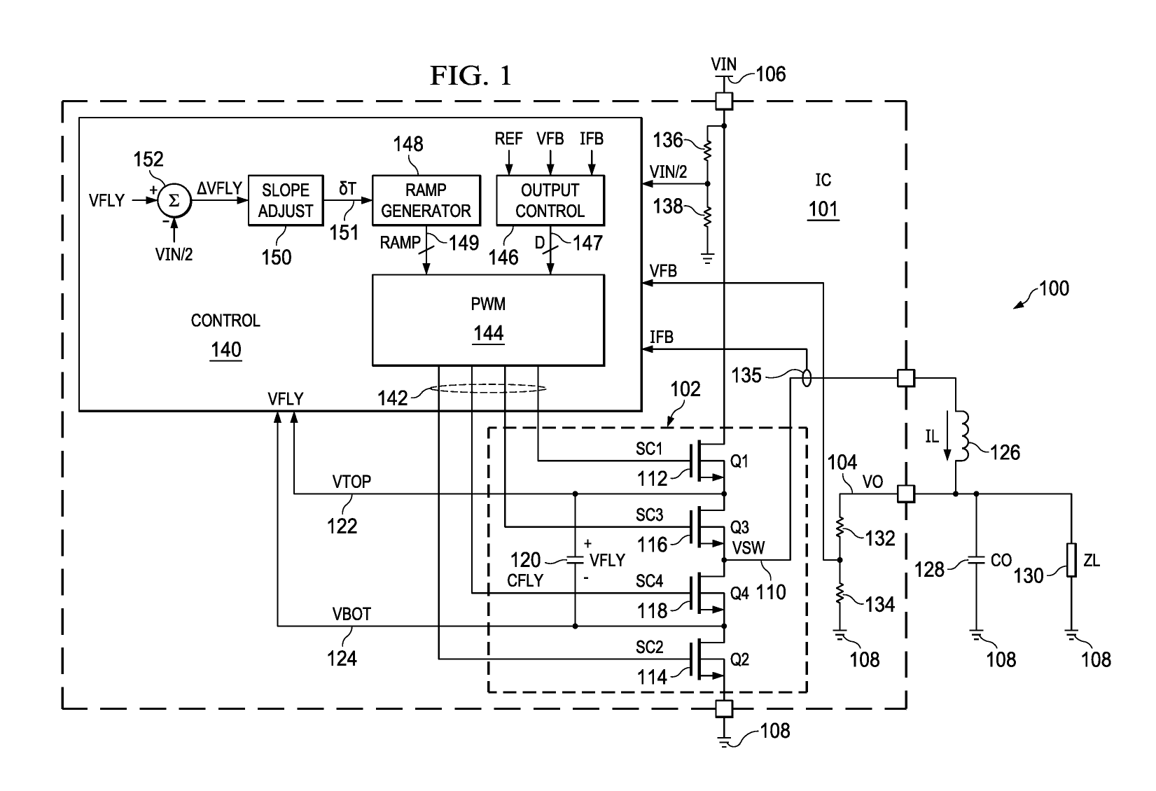

FIG. 1 shows a multi-level power conversion system 100, which in one example includes an integrated circuit (IC) 101 with a converter circuit 102. The IC 101 includes an output node 104 (e.g., IC pin or pad) to deliver an output signal, such as an output voltage signal VO to drive a connected load. The example IC 101 includes an input node 106 (e.g., IC pin or pad) to receive an input signal, such as an input voltage signal VIN. In the illustrated example, the conversion system 100 is a DC-DC converter. When powered, the system 100 converts an input signal VIN at an input node 106 to provide an output signal, such as a voltage output signal VO, to an output node 104. In one example, the converter circuit 102 operates to regulate the output voltage VO according to a reference signal or value REF, which can be an internal reference or can be provided to an output control circuit in the IC 101. The converter circuit 102 includes a switching circuit with transistor switches connected between the input node 106 and a reference voltage node 108 (e.g., a ground reference). The switching circuit is connected to provide a switching node signal to a switching node 110, such as a switching node voltage signal VSW.

The converter circuit 102 in FIG. 1 is a three-level converter that includes switches 112 (labeled Q1), 114 (labeled Q2), 116 (labeled Q3) and 118 (labeled Q4) coupled in a series circuit between the input node 106 and the reference voltage node 108. The switches 112, 114, 116 and 118 operate according to switching control signals SC1, SC2, SC3 and SC4, respectively, to provide a voltage signal VSW at the switching node 110. In other examples, the converter circuit 102 can include more or fewer switches to provide an N-level converter, where N is greater than 2. In the illustrated example, the converter circuit switches 112, 114, 116 and 118 are n-channel MOSFET (e.g., NMOS) transistors operative to turn on according to a corresponding active high switching control signal. In other examples, different transistor switches can be used (e.g., PMOS, bipolar, IGBTs). The first switch 112 in FIG. 1 includes a drain connected to the input node 106 and a source connected to the first internal node 122. The third switch 116 includes a drain connected to the internal node 122, and a source connected to the switching node 110. The fourth transistor 118 includes a drain connected to the switching node 110, and a source connected to the second internal node 124. The second transistor 114 includes a drain connected to the second internal node 124, and a source connected to the reference voltage node 108. The multi-level converter circuit 102 also includes a capacitor 120, referred to herein as a flying capacitor (labeled CFLY). The capacitor 120 is connected between a first internal node 122 and a second internal node 124 of the switching circuit. In one example, the IC 101 includes the flying capacitor 120 as shown in FIG. 1. In another example, the IC 101 includes pins or pads (not shown) to allow connection of an external flying capacitor 120.

The power conversion circuit 100 also includes an inductor 126 coupled between the switching node 110 and the output node 104. In the illustrated example, the IC 101 includes externally accessible pins or pads for connection to the terminals of the inductor 126, including a pin connected to the switching node 110, and a pin or pad connected to the output node 104. In other examples, the inductor 126 can be included in the integrated circuit 101. The configuration of the switching circuit and the inductor 126 provides a buck-type DC-DC converter to provide a controlled output voltage signal VO at the output node 104 by converting input power from the input voltage signal VIN. In the illustrated system 100, an output capacitor 128 (labeled CO) is connected between the output node 104 and the reference voltage node 108, and the output signal VO drives a load 130, (labeled ZL).

The system 100 provides closed loop regulation of the output signal VO according to a feedback signal VFB from a resistive voltage divider circuit formed by divider resistors 132 and 134. The resistors 132 and 134 are connected in series with one another between the output node 104 and the reference voltage node 108, and the feedback signal VFB is created at a center node joining the resistors 132 and 134. In other possible implementations, the voltage feedback signal can be taken directly from the output node 104 (VO), and the control set point or reference (REF in FIG. 1) is scaled accordingly. In some examples, the IC 101 includes a current sensor 135 that senses an inductor current IL flowing in the inductor 126, and provides a current sense feedback signal IFB. Also, the IC 101 includes a second resistive voltage divider circuit including resistors 136 and 138 of generally equal resistances to provide a signal VIN/2 representing half of the input voltage signal VIN.

The IC 101 also includes control circuitry 140, which provides the switching control signals SC1, SC2, SC3 and SC4 to operate the switches 112, 114, 116 and 118, and to control sub-cycle durations as described further hereinbelow. In one example, the control circuitry 140 is implemented as analog circuits that implement the functions described herein. In another example, the control circuitry 140 includes one or more digital processing circuits, and converter circuits (not shown) to convert analog signals to digital signals and vice versa. In certain implementations, internal circuits schematically represented in the control circuitry 140 in FIG. 1 can be implemented, in whole or in part, as firmware or software-executed program instructions.

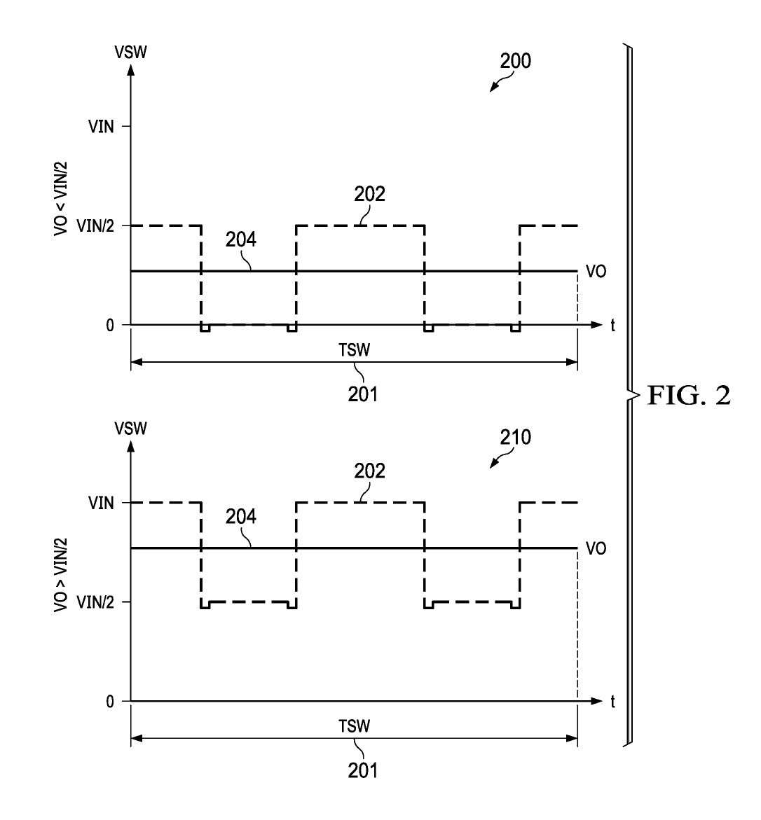

In one example, the control circuitry 140 includes four outputs collectively labeled 142 in FIG. 1 to provide the switching control signals to the switching circuit 102. In this example, the control circuitry 140 includes a pulse width modulation (PWM) circuit 144 that generates the switching control signals SC1, SC2, SC3 and SC4 with a controlled duty cycle to operate the switches 112, 114, 116 and 118 according to (e.g., in response to, or based upon) a duty cycle signal to control the switching node voltage signal VSW at the switching node 110. The controlled duty cycle is adjustable in different switching cycles. As described further hereinbelow in connection with FIG. 2, the switching cycles include first and second sub-cycles with respective first and second sub-cycle durations. The control circuitry 140 also controls the first and second sub-cycle durations in a given switching cycle to control the voltage VFLY across the capacitor 120 while maintaining the duty cycle.

The control circuitry 140 in FIG. 1 also includes an output control circuit 146 that controls the duty cycle of the switching control signals SC1, SC2, SC3 and SC4 that are generated by the PWM circuit 144. In the illustrated example, the output control circuit 146 includes an output 147 coupled to provide the duty cycle signal D to the PWM circuit 144 to control the duty cycle of the switching control signals SC1, SC2, SC3 and SC4. The duty cycle represents a ratio or proportion of time in a given switching cycle during which certain converter switches 112, 114, 116 and/or 118 are turned on. In one example, the output control circuit 146 is an analog circuit, including comparators, signal amplifiers and other circuitry to generate an error signal based on the difference between the voltage feedback signal VFB and the reference (e.g., setpoint) signal REF. In certain examples, the output control circuit 146 also generates the duty cycle signal D at least partially according to (e.g., at least partially in response to, or at least partially based upon) the inductor current feedback signal IFB.

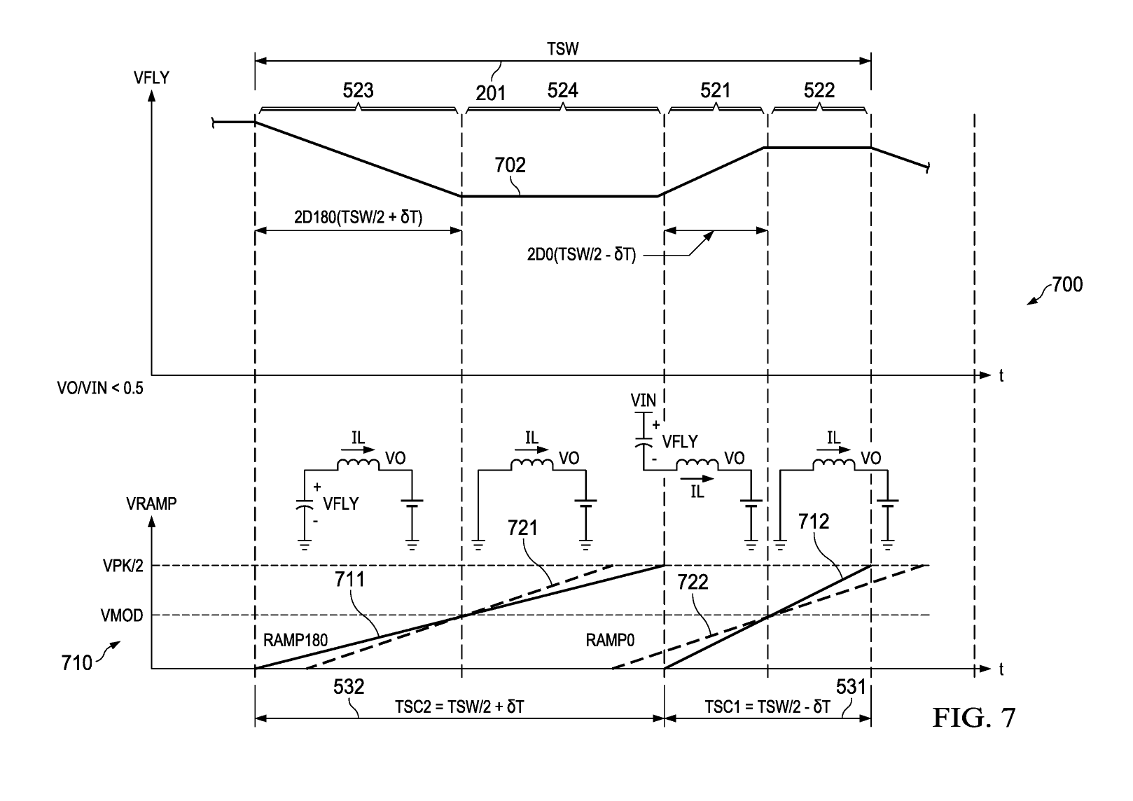

The PWM circuit 144 in one example is an analog circuit with one or more comparators to selectively change the states of the switching control signals SC1, SC2, SC3 and SC4 between first and second states or values (e.g., high and low) in order to selectively turn the corresponding switches 112, 114, 116 and/or 118 on or off in a controlled fashion. In one example, the duty cycle signal D is a value determined by an outer loop control function that represents the on-time of one or more of the switching control signals in a given switching cycle. In one example, the control circuitry 104 can generate a modulation signal (e.g., VMOD in FIG. 7 hereinbelow) as an analog signal having a voltage level corresponding to a duty cycle determined by the output control circuit 146 according to a closed-loop regulation or control function. For example, the output control circuit 146 implements a proportional-integral (PI) or proportional-integral-derivative (PID) closed loop control function to regulate the output signal VO according to the reference signal REF and one or more feedback signals (e.g., VFB, IFB). The comparators of the PWM circuit 144 compare a modulation voltage signal (e.g., VMOD) that corresponds to the duty cycle signal D with a ramp signal RAMP from a ramp generator circuit 148. Any suitable ramp generator circuitry can be used, such as an RC network with a current source, a capacitor and a resistor (not shown), or an inductor current can be used. In further examples, the ramp generator circuitry 148 can be implemented by processor-executed program instructions in a digital domain. In one implementation, the PWM circuit comparators selectively change the states of one or more of the switching control signals SC1, SC2, SC3 and SC4 at the outputs 142 according to (e.g., in response to or based upon) an upward ramp signal RAMP transitioning above the modulation signal (e.g., VMOD) that is derived from the output 147 of the output control circuit 146. In other implementations, one or more functions of the ramp generator circuit 148, the output control circuit 146 and/or the PWM circuit 144 can be implemented by a digital circuit, such as a microprocessor, programmable logic circuit, etc. For example, a digital logic circuit can generate a ramp value, and compare this to a modulation value derived from a closed loop control function implemented as processor-executed program instructions, and generate PWM signals that are provided to a driver circuit to generate the switching control signals at the outputs 142 in a given switching cycle. In one example, the control circuitry 140 generates the pulse width modulated switching control signals SC1, SC2, SC3 and SC4 in each of a series of consecutive switching cycles.

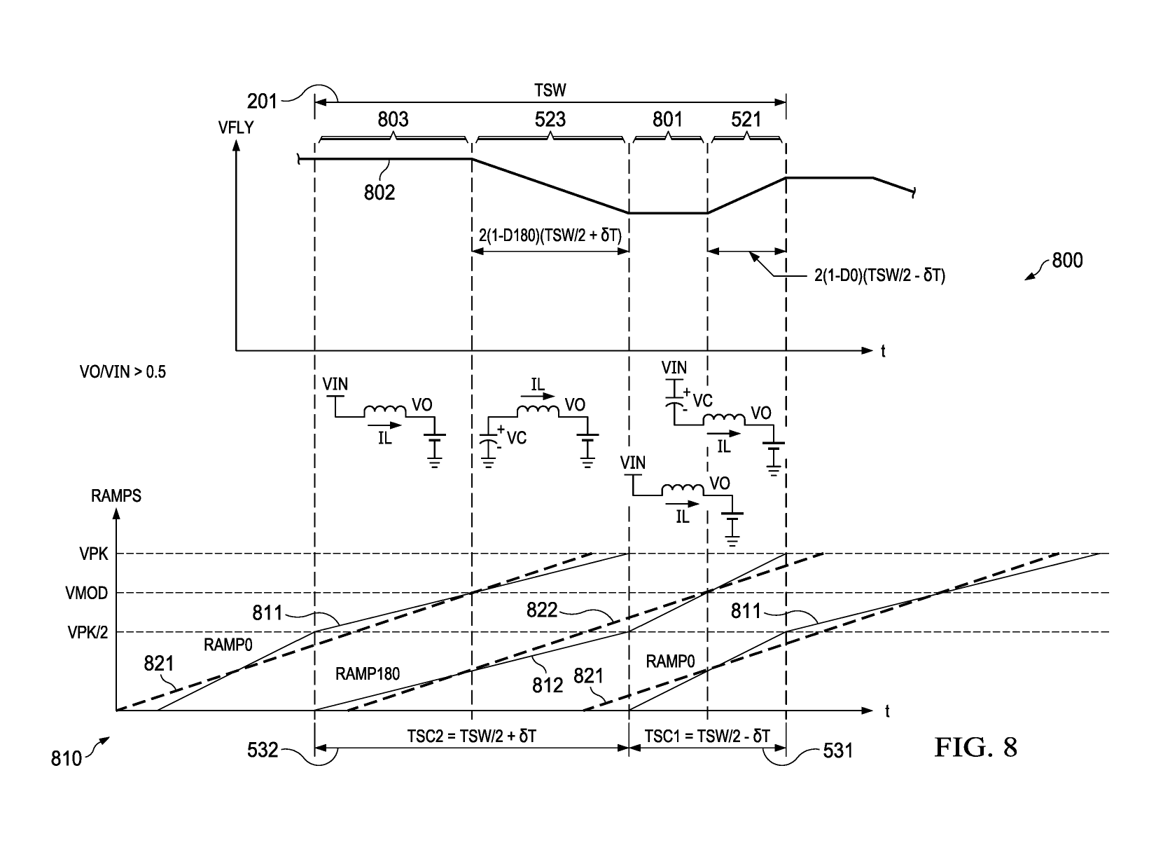

In one example, the control circuitry 140 implements a generally constant switching frequency control implementation in which each consecutive switching cycle has a constant duration, although not a strict requirement of all possible implementations. In the illustrated three-level converter example, each switching cycle includes a respective set of four intervals, because each switching cycle is divided into respective first and second sub-cycles; and each sub-cycle is divided into respective first and second control intervals. In this example, the control circuitry 140 generates the pulse width modulated switching control signals SC1, SC2, SC3 and SC4 to define switching states of the switching circuit for each interval. The ramp generator circuit 148 has an output 149 that provides one or more ramp signals (labeled RAMP in FIG. 1) to the PWM circuit 144 to control the first and second sub-cycle durations TSC1, TSC2 in the given switching cycle 201. In one implementation, the ramp generator circuit 148 provides first and second ramp signals at the output 149, as described further below in connection with FIGS. 7 and 8.

The control circuitry 140 also includes a slope adjustment circuit 150 coupled with the ramp generator circuit 148 to control a slope of the ramp signal or signals RAMP according to the voltage VFLY across the flying capacitor 120. In one example, the slope adjustment circuit 150 has an output 151 that generates and provides a time adjustment signal 6T to the ramp generator circuit 148 according to (e.g., in response to, or based upon) a difference signal AVFLY from a subtractor circuit 152. In this example, the difference signal AVFLY represents the difference between the voltage VFLY across the capacitor 120 and a threshold value. In the illustrated example, moreover, the threshold value is VIN/2, although other threshold signals or values can be used in other implementations. In the example of FIG. 1, the control circuitry 140 monitors the flying capacitor voltage VFLY according to (e.g., in response to, or based upon) received signals VTOP and VBOT that represent the voltages at the top and bottom terminals of the flying capacitor 120 (e.g., the voltages at the internal nodes 122 and 124). The subtractor circuit 152 subtracts the threshold value signal VIN/2 (e.g., from the voltage divider circuit 136, 138) from the flying capacitor voltage signal VFLY, and provides the resulting difference signal AVFLY to the slope adjustment circuit 150. The slope adjustment circuit 150 provides the time adjustment signal 6T to the ramp generator circuit 148 according to (e.g., in response to, or based upon) the difference signal AVFLY.

In operation, the control circuitry 140 controls the first and second sub-cycle durations in the given switching cycle to control the converter capacitor voltage while maintaining the duty cycle in the given switching cycle. Modulating the sub-cycle durations increases/decreases the charge/discharge times of the flying capacitor 120. The control circuitry maintains the effective duty-cycle across a given switching cycle and thus does not disturb the main voltage/current-mode outer control loop. In some examples, the control circuitry 140 maintains the duty cycle in both the first sub-cycle and the second sub-cycle in the given switching cycle. The example control circuitry 140 resolves charge balance problems through inner loop flying capacitor voltage regulation for multi-level converters of three or more levels, without disturbing the output voltage or inductor current loop.

The ramp generator circuit 148 selectively adjusts or otherwise sets the slope of the ramp signal or signals RAMP according to (e.g., in response to, or based upon) the time adjustment signal T. In one example, the ramp generator circuit increases the slope of the ramp signal RAMP in one sub-cycle, and decreases the slope of the ramp signal RAMP in the other sub-cycle to control the first and second sub-cycle durations in a given switching cycle 201. In one example, moreover, the slope adjustment maintains the duty cycle in the given switching cycle. In some examples, moreover, the slope adjustment circuit 150 generates and provides a time adjustment signal 6T proportional to the deviation of the flying capacitor voltage VFLY from the threshold value (e.g., VIN/2). As a result, the control circuitry 140 in this example adjusts the sub-cycle durations proportional to the difference signal AVFLY, so that the difference between the sub-cycle durations in a given switching cycle is greater for larger deviations of the flying capacitor voltage VFLY from the threshold value. In this manner, the control circuitry 140 regulates the flying capacitor voltage VFLY according to the threshold value without adversely affecting the duty cycle during a given switching cycle. As a result, the flying capacitor voltage regulation does not disturb the outer control loop or loops used to regulate the output signal VO.

FIG. 2 shows graphs 200 and 210 of switching node voltage VSW for two different example levels of the output voltage signal. The graphs 200 and 210 illustrate two example steady state operating conditions in the system 100 of FIG. 1 when the control circuitry 140 regulates the switching control duty cycle to drive the voltage output signal VO to a level corresponding to the reference signal REF. The waveforms illustrated in FIG. 2 correspond to a three-level converter implementation. Different signal waveforms and switching states (not shown) can be used for other multi-level converter systems of higher orders (e.g., 4-level converters and above). The graph 200 shows a switching node voltage curve 202 (labeled VO) during an example switching cycle 201 with a total cycle period or duration TSW. The graph 200 shows two transitions of the switch node voltage signal VSW between approximately zero and VIN/2 in the four intervals of the example switching cycle 201 for an output voltage signal VO (curve 204) that is less than VIN/2. The graph 210 in FIG. 2 shows the switch node voltage and output voltage curves 202 and 204 for an example output voltage level above VIN/2. In this condition, the switch node voltage transitions twice between approximately VIN and VIN/2 in the example switching cycle 201. In one example, the control circuitry 140 provides the switching control signals SC1, SC2, SC3 and SC4, so that the switching cycles 201 have equal switching cycle durations TSW. In other implementations, the control circuitry 140 can vary the switching cycle durations TSW of successive switching cycles 201.

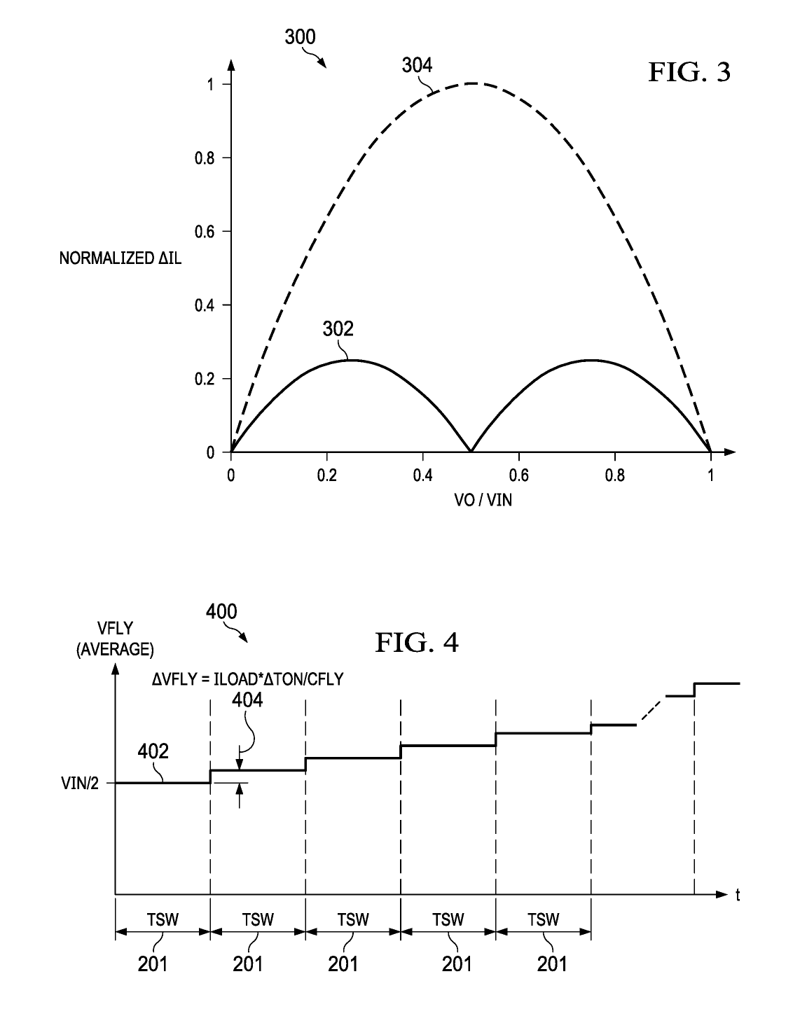

FIG. 3 shows a graph 300 with curves 302 and 304 of normalized inductor current ripple (labeled NORMALIZED ΔIL) as a function of output voltage to input voltage ratio VO/VIN. The curve 304 shows the normalized inductor current ripple for a two-level buck converter (not shown) and the curve 302 shows the normalized inductor current change for the example three-level converter in the system 100 of FIG. 1 for the same switching cycle duration. The three-level switch node toggles at twice the switching frequency compared to a single toggle for a two-level converter. In this manner, the inductor current ripple amount is reduced for the three-level converter implementation. The effective switching frequency doubles for the three-level converter (curve 302) compared with the two-level buck converter (curve 304). Also, the three-level converter (e.g., system 100 in FIG. 1) reduces the switching node voltage VSW by a factor of 2 compared with two-level buck converters. These two factors reduce the inductor current ripple by a factor of 4, allowing reduced switch transistor sizes and increased power density. Also, the described control circuitry 140 facilitates flying capacitor voltage control without disturbance of outer-loop regulation of the output signal VO. Described example multi-level converters facilitate output signal control in combination with the increased power density and other advantages of three or higher level power conversion systems.

FIG. 4 shows a graph 400 including a curve 402 of average flying capacitor voltage (e.g., capacitor voltage signal VFLY in FIG. 1) as a function of time over several switching cycles 201. In this example, the switching cycles 201 have equal duration TSW. The curve 402 illustrates an example of mismatch in on-time that causes drift in the flying capacitor voltage signal VFLY over successive switching cycles 201. In this example, on-time mismatch between charging and discharging states of the flying capacitor 120 in a given switching cycle leads to an offset in the flying capacitor voltage VFLY. The voltage offset AVFLY=ILOAD*ATON/CFLY represents the difference between the flying capacitor voltage and VIN/2, where ILOAD is the output load current of the power conversion system 100, ATON is the on-time mismatch between charging and discharging states and CFLY is the capacitance of the flying capacitor 120. Absent countermeasures, the offset is accumulated in successive switching cycles 201.

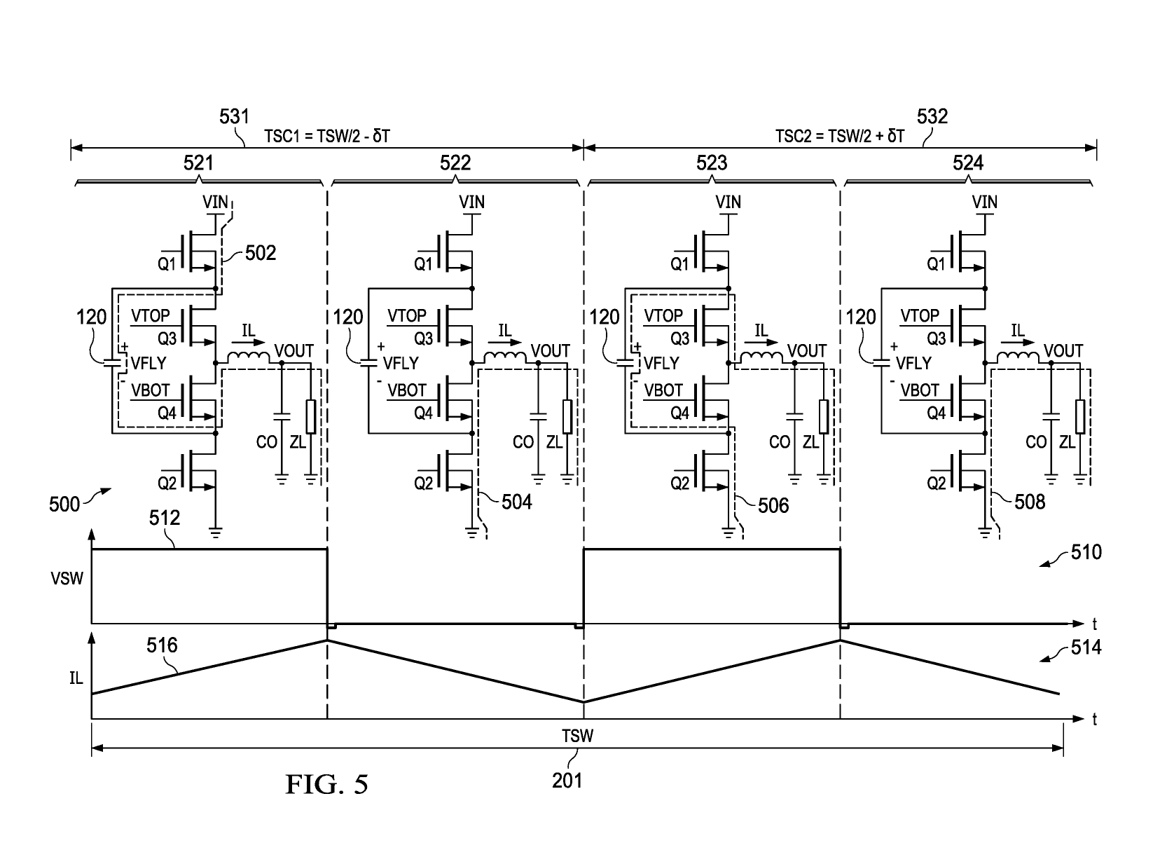

FIG. 5 shows schematic representations 500 of the switching states of the converter circuit 102 in for example intervals of an example switching cycle 201 in the conversion system 100. The example switching cycle includes a first switching state in which the control circuitry 140 turns Q1 and Q4 on, and turns Q2 and Q3 off. In this switching state, current flows along a path 502 from the input node 106 through Q1, the flying capacitor 120, Q4 and the output inductor 126 and the flying capacitor 120 is charged. In the second switching state of FIG. 5, the control circuitry 140 turns Q1 and Q3 off, and turns Q2 and Q4 on. This causes current flow along a path 504 from the reference voltage node through Q2, Q4 and the output inductor. In a third switching state, the control circuitry 140 turns Q2 and Q3 on, and turns Q1 and Q4 off. This switching state discharges the flying capacitor 120 with current flow along a path 506. In a fourth example switching state in FIG. 5, the control circuitry 140 again turns Q1 and Q3 off, and turns Q2 and Q4 on to conduct current along a path 508. In this example, an on-time mismatch in the on time of the first and third switching states can cause accumulated offsets in the flying capacitor voltage VFLY as shown in the example of FIG. 4 over successive switching cycles 201.

FIG. 5 also includes a graph 510 with a curve 512 that shows the switching node voltage signal VSW during the example switching cycle 201. Also, a graph 514 in FIG. 5 includes a curve 516 that shows the inductor current signal IL during the example switching cycle 201. As shown in FIG. 5, the switching cycle 201 includes a first sub-cycle 531 with a first sub-cycle duration TSC1 and a second sub-cycle 532 with a second sub-cycle duration TSC2. The first sub-cycle 531 includes a first interval 521 that corresponds to the first converter circuit switching state (current conduction path 502), and a second interval 522 that corresponds to the second converter circuit switching state (current conduction path 504). The second sub-cycle 532 includes a third switching cycle interval 523 that corresponds to the third switching state (current conduction path 506), and a fourth switching cycle interval 524 that corresponds to the fourth switching state (current conduction path 508).

In one example, the control circuitry 140 in FIG. 1 regulates the flying capacitor voltage VFLY independent of the output control loop duty cycle. In one example, the control circuitry 140 adjust the slope of the RAMP signal generated by the ramp generator circuit 148 to offset the durations TSC1 and TSC2 of the first and second sub-cycles 531 and 532 according to (e.g., in response to, or based upon) the difference (e.g., ΔVFLY) between the flying capacitor voltage (e.g., VFLY) and a threshold value (e.g., VIN/2). In one example, this results in adding an offset (e.g., represented by the adjustment signal value δT in FIG. 1) to one of the sub-cycles 531 and 532 and subtracting the offset from the other one of the sub-cycles 531 and 532. FIG. 5 shows one example in which the first sub-cycle duration TSC1=TSW/2+δT and the second sub-cycle duration TSC2=TSW/2−δT. In particular, the control circuitry 140 controls the first and second sub-cycle durations TSC1 and TSC2 (e.g., selectively decreases one of the first and second sub-cycle durations TSC1, TSC2, and increases the other sub-cycle duration in a given switching cycle 201) to control or regulate the flying capacitor voltage VFLY while maintaining the duty cycle (e.g., D) in the given sub cycle. In some examples, the control circuitry 140 the control circuitry 140 decreases one of the first and second sub-cycle durations TSC1, TSC2 proportional to ΔVFLY (e.g., VFLY−VIN/2) and increases the other sub-cycle duration proportional to ΔVFLY.

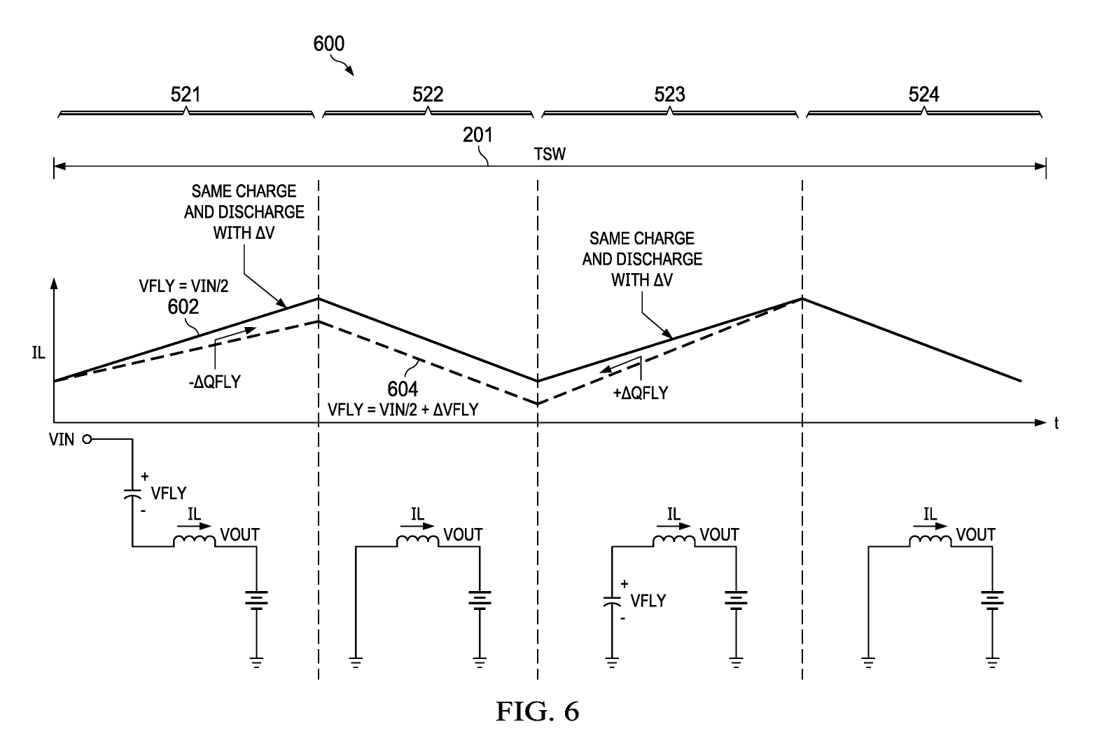

FIG. 6 shows a graph 600 of inductor current IL in an example switching cycle 201 for two different flying capacitor voltage values. The graph 600 illustrates the lack of restoring force in the multi-level converter circuit 102. The graph 600 shows a curve 602 that represents the inductor current where the capacitor voltage is half the input voltage (VFLY=VIN/2). A curve 604 represents the inductor current for the capacitor voltage is offset from VIN/2 by a nonzero difference (e.g., VFLY=VIN/2+ΔVFLY). In this case, even with equal charge and discharge times in the first and third intervals 521 and 523, any imbalance in the flying capacitor voltage will not be remedied without regulation.

FIG. 7 shows a graph 700 including a curve 702 of flying capacitor voltage (e.g., in an example switching cycle 201 with sub-cycles 531 and 532. FIG. 7 also includes a graph 710 of example ramp signals, including curves 711 and 721 that illustrate ramp signals labeled RAMP180, and curves 712 and 722 that show ramp signals labeled RAMPO. The graphs 700 and 710 in FIG. 7 illustrate operation of the power conversion system 100 where the output voltage VO is less than VIN/2. The curves in the graph 710 show ramp signal voltages (VRAMP) in a range from zero through half a peak value (e.g., VPK/2). In one example, the peak ramp voltage value VPK is proportional to the input voltage VIN. The PWM circuit 144 (FIG. 1) modulates the ramp signals 711, 712, 721 and 722 according to a modulation voltage signal (e.g., VMOD which can be derived from the duty cycle signal D described hereinabove) to generate pulse width modulated switching control signals SC1, SC2, SC3 and SC4. When a given one of the ramp signals transitions to the ramp voltage peak value VPK or transitions above the modulation signal, the PWM circuit 144 transitions from one switching state to the next switching state.

In the example of FIG. 7, the ramp generator circuit 148 generates two ramp signals, RAMPO and RAMP180. In this example, RAMPO corresponds to the saw-tooth reference that when compared to VMOD generates the on-time for Q1. RAMP180 corresponds to the saw-tooth reference that when compared to VMOD generates the on-time for Q3. The PWM circuit 144 generates the switching states and transitions in the first sub-cycle 531 (e.g., intervals 521 and 522) according to (e.g., in response to, or based upon) the ramp signal RAMPO. The PWM circuit 144 generates the switching states and transitions in the second sub-cycle 532 (e.g., intervals 523 and 524) according to (e.g., in response to, or based upon) the ramp signal RAMP180. In one example, the output control circuit 146 generates two duty cycle signals, D0 and D180.

The graph 710 shows example ramp signal curves 711 (RAMP 180) and 712 (RAMPO) with ramp slopes adjusted by the slope adjust circuit 150 to compensate the sub-cycles to regulate the flying capacitor voltage VFLY in the illustrated switching cycle 201. In this example, the flying capacitor voltage begins above the threshold value (e.g., VFLY>VIN/2) and the difference ΔVFLY is positive. The slope adjustment circuit 150 generates a positive δT signal according to the positive ΔVFLY signal from the subtractor 152. The ramp generator circuit 148 generates the ramp signals RAMPO (curve 712) and RAMP180 (curve 711) to shorten the duration TSC1 of the first sub-cycle 532 by δT and to lengthen the duration TSC2 of the second sub-cycle 532 by δT. In this example, the first switching cycle interval 521 (e.g., CFLY charging) has an interval duration 2D0(TSW/2-δT) and the third switching cycle interval 523 (e.g., CFLY discharging) has an interval duration 2D180(TSW/2+ST). In general, the ramp signal RAMP180 starts when RAMPO equals half the ramp peak (VPK/2). The slope of RAMPO increases when VFLY>VIN/2 and RAMP180 starts sooner than when ΔVFLY=0. The slope of RAMP180 decreases when VFLY>VIN/2 and RAMPO starts later than when ΔVFLY=0. The slope of RAMPO decreases when VIN/2>VFLY and RAMP180 starts later than when ΔVFLY=0. The slope of RAMP180 increases when VIN/2>VFLY and RAMPO starts sooner than when ΔVFLY=0.

The graph 710 in FIG. 7 also shows example ramp signals RAMPO (curve 722) and RAMP180 (curve 721) for the situation in which the flying capacitor voltage VFLY is equal to the threshold value (e.g., VFLY=VIN/2), and δT is zero. For this situation, the sub-cycle durations are equal (TSC1=TSC2). In some described examples, the control circuitry 140 modulates the sub-cycle durations TSC1 and TSC2 to counteract ΔVFLY changes from the threshold value. If VFLY is greater than VIN/2, the circuitry 140 increases the duration of the VFLY discharge state and the corresponding sub-cycle proportionally, in order to maintain the effective sub-cycle duty cycle the same as with zero ΔVFLY. Similarly, the control circuitry 140 decreases the duration of the VFLY charge state and corresponding sub-cycle proportionally. If VFLY is less than VIN/2, the control circuitry 140 performs the opposite adjustments. In this example, the inner-loop capacitor voltage regulation charges VFLY if it is below VIN/2 and discharges VFLY if it is above VIN/2, by adjusting the charge/discharge times of the capacitor 120. The inductor 126 sees similar volt-seconds for each sub-cycle to ensure minimal asymmetry on the inductor current and act orthogonally to for any current-mode controllers because the control circuitry 140 maintains the outer-loop duty cycle the same throughout the sub-cycles 531 and 532. In this manner, the flying capacitor voltage regulation does not disturb the output voltage regulation.

FIG. 8 illustrates operation of the system 100 when where the output voltage VO is greater than VIN/2 (VO/VIN is greater than 0.5). A graph 800 in FIG. 8 includes a curve 802 of flying capacitor voltage (VFLY). A graph 810 includes curves 811, 812, 821 and 822 of example ramp signals RAMP180 and RAMPO. In this example, the first sub-cycle 531 includes a first interval 801 where the control circuitry 140 turns Q1 and Q3 on and turns Q2 and Q4 off, followed by the interval 521 described hereinabove. The second sub-cycle 532 includes an interval 803 with Q1 and Q3 on and Q2 and Q4 off followed by the interval 523 described hereinabove. The graph 810 shows example ramp signal curves 811 (RAMP 180) and 812 (RAMPO) with ramp slopes adjusted by the slope adjust circuit 150 to compensate the sub-cycle durations TSC1 and TSC2 to regulate the flying capacitor voltage VFLY. The control circuitry 140 in this example modulates the ramp slopes (e.g., curves 811 and 812) with opposing polarity when the ramp signal is above VPK/2. The polarity change ensures that the effective duty-cycle for each sub-cycle is maintained constant to avoid affecting the voltage or current-mode control of the output signal VO. The graph 810 in FIG. 8 also shows example ramp signals RAMPO (curve 822) and RAMP180 (curve 821) for the situation in which the flying capacitor voltage VFLY is equal to the threshold value (e.g., VFLY=VIN/2), and δT is zero. For this situation, the sub-cycle durations are equal (TSC1=TSC2).

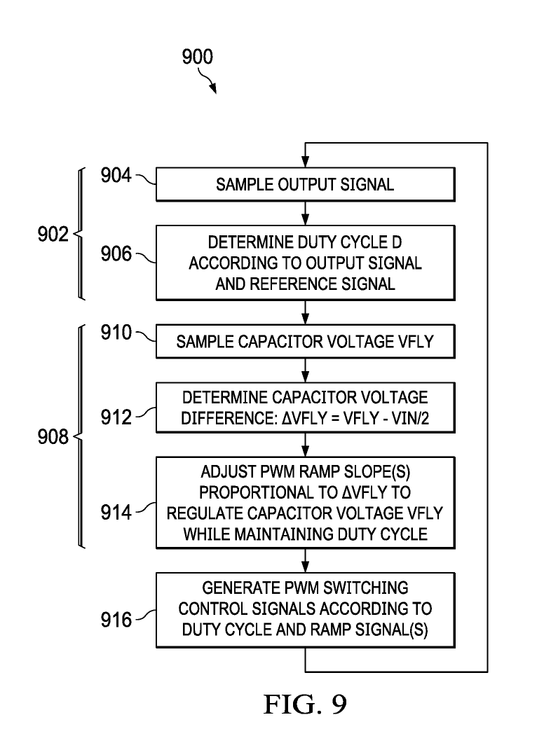

FIG. 9 shows a method 900 of controlling a multi-level power conversion system, such as the system 100 in FIG. 1, for an example switching cycle. The method 900 includes controlling the duty cycle according to a feedback signal (e.g., VFB, IFB) at 900 in a given switching cycle to regulate the output signal VO, and controlling first and second sub-cycle durations (e.g., TSC1 and TSC2) at 908 in the given switching cycle to control a voltage across a capacitor (e.g., 120) while maintaining the duty cycle. The method 900 also includes generating PWM switching control signals (e.g., SC1, SC2, SC3, SC4) according to the controlled duty cycle to operate switches (e.g., 112, 114, 116, 118) at 916. In some examples, the duty cycle control at 902 includes sampling an output signal (e.g., VO and/or IL) at 904, and determining a duty cycle (e.g., D) according to the sampled output signal and a reference signal. In some examples, controlling the first and second sub-cycle durations at 908 includes sampling the capacitor voltage (e.g., VFLY) at 910. The sub-cycle duration control at 908 in this example also includes determining the capacitor voltage difference (e.g., ΔVFLY=VFLY−VIN/2) at 912, and adjusting one or more PWM ramp slopes at 914 to regulate the capacitor voltage VFLY while maintaining the duty cycle. In one example, the ramp slope adjustment at 914 is proportional to ΔVFLY. In some examples, the sub-cycle duration adjustment at 914 includes decreasing one of the first and second sub-cycle durations (e.g., TSC1 or TSC2) proportional to ΔVFLY, and increasing 914 the other sub-cycle duration proportional to ΔVFLY. In some implementations, the sub-cycle duration control at 914 includes increasing the slope of a first ramp signal (e.g., RAMPO or RAMP180) to decrease one of the sub-cycle durations proportional to ΔVFLY, and decreasing the slope of a second ramp signal to increase the other sub-cycle duration proportional to ΔVFLY.

Modifications are possible in the described embodiments, and other embodiments are possible, within the scope of the claims.

1. A power conversion system to convert an input signal at an input node into an output signal at an output node, the power conversion system comprising:
a converter circuit, including:
a switching circuit connected to a switching node, the switching circuit including switches coupled between the input node and a reference voltage node, the switches being coupled to generate a voltage signal at the switching node according to switching control signals; and
a capacitor connected between first and second internal nodes of the switching circuit;
an inductor coupled between the switching node and the output node; and
control circuitry that includes a subtractor having a capacitor voltage input coupled to the capacitor, an input voltage input coupled to the input node, and a difference voltage output, the control circuitry to:
generate the switching control signals as pulse width modulation (PWM) signals having a duty cycle to control the output signal, the duty cycle being adjustable in different switching cycles, each switching cycle including a respective first sub-cycle with a first sub-cycle duration and a respective second sub-cycle with a second sub-cycle duration; and
control a given switching cycle's first and second sub-cycle durations in response to the difference voltage output of the subtractor to control a voltage across the capacitor while maintaining the given switching cycle's duty cycle.

2. The power conversion system of claim 1, wherein the control circuitry is coupled to:
generate the switching control signals to have equal switching cycle durations; and
selectively decrease one of the given switching cycle's first and second sub-cycle durations, and increase the other one of the given switching cycle's first and second sub-cycle durations to control the voltage across the capacitor while maintaining the given switching cycle's duty cycle.

3. The power conversion system of claim 2, wherein the control circuitry is coupled to:
decrease one of the given switching cycle's first and second sub-cycle durations proportional to a difference voltage signal on the difference voltage output; and
increase the other one of the given switching cycle's first and second sub-cycle durations proportional to the difference voltage signal on the difference voltage output.

4. The power conversion system of claim 3, in which the input voltage input is coupled to a voltage that is half a voltage of the input signal.

5. The power conversion system of claim 2, wherein the control circuitry is coupled to maintain the given switching cycle's duty cycle in the first sub-cycle and the second sub-cycle.

6. The power conversion system of claim 2, wherein the control circuitry includes:
an output control circuit to generate a duty cycle signal to control the duty cycle of the switching control signals according to a feedback signal to regulate the output signal;
a pulse width modulation (PWM) circuit to generate the switching control signals according to the duty cycle signal from the output control circuit and according to a ramp signal;
a ramp generator circuit to generate the ramp signal to the PWM circuit; and
a slope adjustment circuit coupled with the ramp generator circuit to control a slope of the ramp signal according to the voltage signal on the difference voltage output.

7. The power conversion system of claim 1, wherein the control circuitry includes:
an output control circuit to generate a duty cycle signal to control the duty cycle of the switching control signals according to a feedback signal to regulate the output signal; and
a pulse width modulation (PWM) circuit to generate the switching control signals according to the duty cycle signal from the output control circuit.

8. The power conversion system of claim 7, wherein the control circuitry further includes:
a ramp generator circuit to generate a ramp signal to the PWM circuit; and
a slope adjustment circuit coupled with the ramp generator circuit to control a slope of the ramp signal according to the voltage signal on the difference voltage output.

9. The power conversion system of claim 8, wherein the slope adjustment circuit is coupled to:
increase a slope of a first ramp signal to decrease one of the given switching cycle's first and second sub-cycle durations proportional to the voltage signal on the difference voltage output; and
decrease a slope of a second ramp signal to increase the other one of the given switching cycle's first and second sub-cycle durations proportional to the voltage signal on the difference voltage output.

10. The power conversion system of claim 9, in which the input voltage input is coupled to a voltage that is half a voltage of the input signal.

11. The power conversion system of claim 1, wherein the converter circuit is an N-level converter, and N is greater than 2.

12. A control circuit to control a multi-level power conversion system, the control circuit comprising:
a pulse width modulation (PWM) circuit to generate switching control signals having a duty cycle to operate switches to control a voltage signal at a switching node, the duty cycle being adjustable in different switching cycles, and each switching cycle including a respective first sub-cycle with a first sub-cycle duration and a respective second sub-cycle with a second sub-cycle duration;
an output control circuit to generate a duty cycle signal to control the duty cycle according to a feedback signal, to regulate an output signal at an output node that is coupled to the switching node;
a ramp generator circuit to generate a ramp signal to the PWM circuit to control the given switching cycle's first and second sub-cycle durations;
a slope adjustment circuit coupled with the ramp generator circuit to control a slope of the ramp signal according to a difference voltage on a difference voltage input; and
a subtractor having a capacitor voltage input coupled to a capacitor of the power conversion system, an input voltage input coupled to an input node of the power conversion system, and a difference voltage output coupled to the difference voltage input.

13. The control circuit of claim 12, wherein the slope adjustment circuit is coupled to:
increase a slope of a first ramp signal to decrease one of the given switching cycle's first and second sub-cycle durations proportional to the difference voltage; and
decrease a slope of a second ramp signal to increase the other one of the given switching cycle's first and second sub-cycle durations proportional to the difference voltage.

14. The control circuit of claim 13, in which the input voltage input is coupled to a voltage that is half a voltage of the input node.

15. The control circuit of claim 12, wherein the slope adjustment circuit is coupled to maintain the given switching cycle's duty cycle in the first sub-cycle and the second sub-cycle.

16. The control circuit of claim 12, wherein the PWM circuit, the output control circuit, the ramp generator circuit, the slope adjustment circuit, and the subtractor are formed as a single integrated circuit.

17. The control circuit of claim 16, wherein the single integrated circuit includes a converter circuit of the power conversion system, and wherein the converter circuit includes:
a switching circuit connected to the switching node, the switching circuit including switches coupled between an input node and a reference voltage node, the switches being coupled to generate a voltage signal at the switching node to control the output signal according to switching control signals; and
the capacitor is connected between first and second internal nodes of the switching circuit.

18. A method of controlling a multi-level power conversion system, the method comprising:
generating pulse width modulation (PWM) signals having a duty cycle to operate switches to convert an input signal at an input node into an output signal at an output node, the duty cycle being adjustable in different switching cycles, each switching cycle including a respective first sub-cycle with a first sub-cycle duration and a respective second sub-cycle with a second sub-cycle duration;
controlling the duty cycle according to a feedback signal in a given switching cycle to regulate the output signal;
controlling the given switching cycle's first and second sub-cycle durations to control a voltage across a capacitor of the power conversion system while maintaining the given switching cycle's duty cycle; and
the controlling the durations including subtracting half of a voltage of the input signal from a voltage across the capacitor to produce a difference voltage that controls the durations.

19. The method of claim 18, wherein controlling the first and second sub-cycle durations comprises:
decreasing one of the given switching cycle's first and second sub-cycle durations proportional to the difference voltage; and
increasing the other one of the given switching cycle's first and second sub-cycle durations proportional to the difference voltage.

20. The method of claim 18, wherein controlling the first and second sub-cycle durations comprises:
increasing a slope of a first ramp signal to decrease one of the given switching cycle's first and second sub-cycle durations proportional to the difference voltage; and
decreasing a slope of a second ramp signal to increase the other one of the given switching cycle's first and second sub-cycle durations proportional to the difference voltage.
